(19) United States
(12) Patent Application Publication
(10) Pub. No.: US 2026/0193477 A1
(43) Pub. Date: Jul. 9, 2026

(54) BINDERS FOR ENERGY CONVERSION AND STORAGE DEVICES

(71) Applicant: CAP-XX LIMITED, New South Wales (AU)

(72) Inventors: Alexander BILYK, New South Wales (AU); Andrzej KUCHARZEWSKI, New South Wales (AU); Thomas Keith Ellis, New South Wales (AU)

(21) Appl. No.: 19/134,863

(22) PCT Filed: Dec. 4, 2023
(86) PCT No.: PCT/AU2023/051252

§ 371 Date: Jun. 2, 2025

(30) Foreign Application Priority Data
Dec. 2, 2022 (AU) 2022903689
Dec. 2, 2022 (AU) 2022903690

(51) Int. Cl. C09D 5/24; C08K 3/04; C08K 7/24; C09D 7/61; C09D 125/18; H01G 11/38; H01M 4/587; H01M 4/62

(52) U.S. Cl. CPC C09D 5/24; C09D 7/61; C09D 125/18; H01G 11/38; H01M 4/587; H01M 4/622; C08K 3/04; C08K 7/24; C08K 2201/001

(57) ABSTRACT

Described herein are electrode active layers for energy conversion or storage devices, such as supercapacitors or batteries, and which comprise an active material and a binder comprising a salt of a sulfonated polymer. Also described herein are slurries for producing such active layers, composite electrodes comprising such active layers, and uses of such active layers in energy conversion or storage devices, as well as methods of making such active layers.

### FIELD OF THE INVENTION

The present invention relates to binders for use in energy conversion and storage devices. In particular, the invention relates to polymeric materials containing ionically charged functional groups that function as binders. The binders herein may be used for providing improved performance in energy conversion and storage devices such as supercapacitors, but the invention herein is not limited to that particular use.

### BACKGROUND OF INVENTION

Any discussion of the prior art throughout the specification should in no way be considered as an admission that such prior art is widely known or forms part of common general knowledge in the field.

Energy conversion and storage devices are used widely in a variety of appliances and applications. Capacitors are one such device, and enable fast, high power delivery of energy, but the amount of energy delivered is very low (i.e., they have low capacitance). Batteries are another, and are good at storing much larger amounts of energy than capacitors, but compromise design to enable functionally adequate power delivery. Sitting between these devices in terms of energy versus power are supercapacitors, which generally enable fast, high power delivery of relatively high amounts of energy.

Supercapacitors (also known as ultracapacitors) can be generalised as either electrical double layer capacitors (EDLCs), pseudocapacitors or hybrid capacitors. EDLCs store energy by means of separation of electrostatic charge, pseudocapacitors (also known as electrochemical capacitors) store energy by redox processes but have charge and discharge characteristics of a capacitor, and hybrid capacitors store energy as mixture of redox and electrostatic charge. Like batteries, supercapacitors generally include two opposed electrodes electrically isolated by an intermediate electronically insulating separator which is porous and permeated by an electrolyte. Two current collecting terminals generally connect to and extend from respective electrodes for allowing external access to the electrodes, and the entire unit is sealed in packaging to prevent in ingress of water and air, and the egress of electrolyte.

Capacitance, or the ability to store an electrical charge, is proportional to the area of overlap of the charged plates and inversely proportional to the distance between the plates. Accordingly, the performance of capacitors using conventional materials is limited by their dimensions. To overcome this issue, the present Applicant has disclosed supercapacitor devices that overcome the dimensionality problem by using an extremely high surface area carbon as a plate coating material; see WO 98/054739, WO 99/053510, WO 00/016352, WO00/034964, WO 01/004920, WO 01/089058 and WO 12/151618, the contents of each of which are incorporated herein by reference. The electrodes consist of metal current collectors, a coating material typically formed from particulate carbon, and a binder, which is used for adhering the carbon to itself and to the associated current collector. The coated electrodes are separated by a separator and either stacked or wound together and disposed within a housing that contains an electrolyte.

The power performance of supercapacitors is strongly influenced by the internal resistance or equivalent series resistance (ESR) of the device, where lower ESR for a device gives better power performance. The ESR is the sum of the resistance of all the materials, for instance, current collector, active material, binder, separator, electrolyte and all internal and external contact resistances.

As one component of the overall system, the binder used in supercapacitors impacts the ESR and therefore device performance. Binders are chemicals that provide cohesive strength to hold together materials that make up the electrode active layer, provide adhesive strength to hold the electrode active layer on the current collector, and provide a means for electrical connection to charge and discharge the electrode. An ideal binder should interfere as little as possible with the function of materials in the electrode active layer, whilst still providing the necessary cohesion and adhesion functions. Binders may also require flexibility so that the electrode active layer is not adversely affected by mechanical stresses, for example bending or vibrations, that a device may experience over its operating lifetime. Typical binders used in the art include carboxymethyl cellulose (CMC), styrene butadiene (SBR), polytetrafluoroethylene (PTFE), poly(vinylidene fluoride) (PVDF), poly(tetrafluoroethylene), polyvinyl fluoride, ethylene-propylene-diene copolymer, and styrene-butadiene rubber, or copolymers and/or variations thereof. Many of the binders used in supercapacitors are also used as binders for battery electrodes.

Binders are generally mixed with the materials that make up the electrode active layer in a liquid carrier, such as water or an organic solvent, and the resulting slurry or suspension is then coated onto a substrate and dried to drive off the liquid carrier.

Due to environmental concerns, there is a significant demand for binders that are compatible with aqueous coating processes. CMC, polyacrylic acid (PAA) or polyvinyl alcohols (PVA) are each compatible with aqueous processing, but have drawbacks such as that they contain reactive hydroxyl groups that reduce stability and cause gas formation, contain impurities such as chloride, and/or have poor dispersant qualities. Other water dispersible binders in the form of latex particles such as SBR, PTFE and PVDF require dispersing agents to stabilise the latex particles, which can reduce the performance of devices, and often require the addition of adhesion promoters. These issues relating to binders in supercapacitors also apply in battery energy storage applications.

As the field of energy conversion and storage devices evolves and the applications become more demanding, there is an ongoing need for new components, including binders, that exhibit better stability and operational characteristics, including improved ESR performance, and/or that are compatible with environmentally friendly processing methods.

It is an object of the present invention to overcome or ameliorate one or more disadvantages of the prior art, or at least to provide a useful alternative.

### SUMMARY OF THE INVENTION

According to a first aspect the present invention, there is provided an electrode active layer for an energy conversion or storage device, comprising: an active material; and a binder comprising a salt of a sulfonated polymer.

The following features may be used in accordance with the first aspect above, either alone or in any suitable combination.

The sulfonated polymer may comprise substituted C₂ to C₆ linear or branched alkene monomers. The substituted C₂ to C₆ linear or branched alkene monomers may comprise, as a substituent, one or more of: —R₁SO₃⁻, —R₁ArSO₃, —ArR¹SO₃⁻, —ArSO₃— or —C(═O)NHR₁SO₃⁻, —C(═O)NHR₁ArSO₃⁻, —C(═O)NHArR₁SO₃⁻; wherein R₁═C₁ to C₆ linear or branched alkyl group or a bond; and Ar=aryl group. Ar may be a phenyl group. The sulfonated polymer may comprise benzenesulfonate groups.

The sulfonated polymer may comprise monomers comprising one sulfonate group per monomer. In some embodiments, the sulfonated polymer comprises monomers comprising one benzenesulfonate group per monomer. The sulfonated polymer may comprise one or more monomers selected from: styrene sulfonate, vinyl sulfonate, 2-acrylamido-2-methyl-1-propanesulfonate, 2-propene-1-sulfonate, or 2-methyl-2-propene-1-sulfonate. In one embodiment, the monomers are styrene sulfonate.

The salt of the sulfonated polymer may comprise one or more counterions selected from: a Group I metal cation, a Group II metal cation, a transition metal cation, a quaternary ammonium cation, or a nitrogen-containing heterocyclic cation. The salt of the sulfonated polymer may comprise one or more counterions selected from lithium, potassium, sodium, caesium, magnesium, and calcium cations.

The salt of the sulfonated polymer may comprise one or more counterions selected from an optionally substituted alkylammonium cation, such as tetramethylammonium, tetraethylammonium, tetrapropylammonium, or tetrabutylammonium, or a 2-(methylthio)ethylammonium cation, or a nitrogen-containing heterocyclic cation such as spiro-bis-pyrrolidinium (SBP), N,N-dimethylpyrrolidinium, N-methyl-N′-propylpyrrolidinium, N,N′-dimethylimidazolium, N-methyl-N′-ethylimidazolium or N-methyl-N′-propylimidazolium.

The sulfonated polymer may have an average molecular mass of from about 20,000 g/mol to about 2,000,000 g/mol. In one embodiment, the sulfonated polymer has an average molecular mass of from about 20,000 g/mol to about 1,000,000 g/mol. In one embodiment, the sulfonated copolymer has an average molecular mass of from about 20,000 g/mol to about 2,000,000 g/mol.

The binder may comprise at least 30% by weight of the salt of the sulfonated polymer. In one embodiment, the binder comprises at least 50% by weight of the salt of the sulfonated polymer. In one embodiment, the binder comprises at least 90% by weight of the salt of the sulfonated polymer.

The sulfonate polymer may be a copolymer comprising two or more different sulfonated monomers, or may be a copolymer comprising one or more sulfonated monomers and at least one other monomer, wherein the sulfonated monomers comprise one sulfonate group per monomer, optionally one benzenesulfonate group per monomer, and wherein the at least one other monomer is devoid of sulfonate groups, optionally wherein the at least one other monomer is selected from one or more of 1,2-difluoroethylene, tetrafluoroethylene, styrene, butadiene, maleic anhydride, maleic acid or a salt thereof, acrylic acid or a salt thereof, methacrylic acid or a salt thereof, or butylacrylic acid or a salt thereof.

The binder may comprise a mixture of two or more different salts of sulfonated polymers, or may comprise a mixture of a salt of a sulfonated polymer and at least one other polymer. The other polymer may be selected from PVDF, PTFE, SBR or an acrylic-based polymer. The active material may be an amorphous carbon, such as may be activated carbon.

The electrode active layer may further comprise a conductive material, such as a conductive carbon.

According to a second aspect of the present invention, there is provided a composite electrode, comprising: the electrode active layer of the first aspect above on a conductive surface.

According to a third aspect of the present invention, there is provided an energy storage device comprising a composite electrode according to the second aspect above. The energy storage device may be a supercapacitor or may be a battery. Accordingly, herein is provided a supercapacitor comprising a composite electrode according to the second aspect above. Also herein is provided a battery comprising a composite electrode according to the second aspect above.

According to a fourth aspect of the present invention, there is provided use of a salt of a sulfonated polymer as a binder in an electrode active layer of a composite electrode.

According to a fifth aspect of the present invention, there is provided an electrode slurry for producing an electrode active layer, the electrode slurry comprising: an active material; a binder comprising a salt of a sulfonated polymer; and solvent.

The following features may be used in accordance with the fifth aspect above, either alone or in any suitable combination.

The electrode slurry may comprise from 50 to 95 wt % solvent. The solvent may be water. The electrode slurry may comprise from 1 to 30 wt % of binder on a solids basis, such as of from 2 to 20 wt %. The slurry may be a substantially homogenous dispersion of the active material.

According to a sixth aspect of the present invention, there is provided a method of making an electrode active layer, comprising: applying an electrode slurry according to the fifth aspect above to a current collector; and drying the electrode slurry to remove the solvent.

Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

It should be understood that any numerical range recited herein is intended to include all sub-ranges subsumed therein. For example, a range of “from x to y” or “between x and y” is intended to include all sub-ranges between x and y and also range end points x and Y.

As used herein, the singular forms “a,” “an,” and “the” may refer to plural articles unless specifically stated otherwise.

### BRIEF DESCRIPTION OF THE DRAWINGS

Embodiments of the invention will now be described, by way of example only, with reference to the accompanying drawings in which:

FIG. 1 shows the ESR rise rate over time of a supercapacitor containing an electrode comprising a sodium polystyrene sulfonate polymer (MW=100,000 g/mol) binder in accordance with one embodiment of the present invention compared to the ESR rise rate for an equivalent supercapacitor containing conventional CMC binder;

FIG. 2 shows the capacitance rise rate over time of the same supercapacitors as FIG. 1;

FIG. 3 shows the frequency response (Bode magnitude plot) for capacitance for the same supercapacitors as FIG. 1;

FIG. 4 shows the Bode phase plot for the same supercapacitors as FIG. 1;

FIG. 5 shows the internal pressures of the same supercapacitors as FIG. 1;

FIG. 6 shows the ESR rise rate over time of a supercapacitor containing an electrode comprising a sodium polystyrene sulfonate polymer (MW=70,000 g/mol) binder in accordance with one embodiment of the present invention compared to the ESR rise rate for the PSS supercapacitor in FIG. 1;

FIG. 7 shows the capacitance rise rate over time of the same supercapacitors as FIG. 6;

FIG. 8 shows the ESR rise rate over time of supercapacitors containing an electrode comprising polystyrene sulfonate polymer (MW=75,000 g/mol) binders with either Ca or Mg counterions in accordance with certain embodiments of the present invention;

FIG. 9 shows the capacitance rise rate over time of the same supercapacitors as FIG. 8;

FIG. 10 shows the ESR rise rate over time of supercapacitors containing an electrode comprising polystyrene sulfonate polymer (MW=75,000 g/mol) binders with either Li, K or Cs counterions in accordance with certain embodiments of the present invention;

FIG. 11 shows the capacitance rise rate over time of the same supercapacitors as FIG. 10;

FIG. 12 shows the capacitance rise rate overtime of asymmetric supercapacitors containing an electrode comprising a polystyrene sulfonate polymer binder in accordance with one embodiment of the present invention and an electrode containing conventional binder SBR;

FIG. 13 shows the ESR rise rate over time of the same supercapacitors as FIG. 12;

FIG. 14 shows the EIS Nyquist plot for the same supercapacitors as FIG. 12;

FIG. 15 shows the Bode phase plot for the same supercapacitors as FIG. 12;

FIG. 16 shows the EIS resistance Bode plot for the same supercapacitors as FIG. 12;

FIG. 17 shows the EIS capacitance Bode plot for the same supercapacitors as FIG. 12;

FIG. 18 shows the ESR rise rate over time of supercapacitors containing an electrode comprising polystyrene sulfonate-maleic acid copolymer (MW=20,000 g/mol) binders in accordance with certain embodiments of the present invention; and,

FIG. 19 shows the capacitance rise rate over time of the same supercapacitors as FIG. 18.

### DETAILED DESCRIPTION OF THE INVENTION

The invention described herein relates to binders comprising polymeric materials comprising sulfonate functional groups that find use in electrode active layers as components of energy conversion and storage devices. More particularly, the disclosure herein encompasses electrode active layers for energy conversion or storage devices that comprise an active material, and a binder comprising a salt of a sulfonated polymer.

The present inventors have discovered that salts of sulfonated polymers have particular utility as binders in electrode active layers. Moreover, when used as binders, the ESR rise in otherwise equivalent devices is significantly lower using salts of sulfonated polymers than when the standard binder CMC is used. Surprisingly, the present inventors have also discovered that salts of sulfonated polymers have comparable active material dispersion properties in aqueous systems compared to CMC. Dispersive properties are an important characteristic of binders, as current processes generally comprise applying a slurry containing binder, solvent and active materials to a conductive surface. Any inhomogeneity and aggregation/agglomeration of particles in the slurry may therefore be reflected in the deposited electrode active layer. In electrode slurries containing mixtures of particles, such as active and conductive materials, disaggregation and even dispersion of materials in the slurry can optimise electrode/electrolyte contacts and conductivity throughout the dried electrode active layer, and therefore deliver performance benefits to energy conversion/storage devices. Without wishing to be bound by any particular theory, the excellent dispersive qualities of the binders described herein results in marked improvement in the life performance of supercapacitors utilising such binders compared to supercapacitors using CMC as a binder, as measured by both ESR rise rate and capacitance loss over time, as well as improved frequency response. Additionally, the chemical composition of the binders herein advantageously avoids chemical side reactions during charge and discharge cycles, provides good adhesion to the current collector, and/or provides good cohesion between binder and active.

In some embodiments, the salts of sulfonated polymers described herein are soluble in water, which allows environmentally friendlier aqueous processing to be used to produce electrode active layers.

Finally, when used as binders, the salts of sulfonated polymers described herein advantageously reduce gas build up during use compared to conventional CMC binders. Gas build up can cause premature device failure. Further advantages of the binders described herein will be apparent in the following description.

Although certain sulfonated polymers are known for their ionic character and therefore have found use to date in charge transfer or membrane applications, the present inventors are the first to discover their utility as binders, particularly in composite electrodes useful in energy conversion and storage devices. The unexpected properties of salts of sulfonated polymers in this particular application in the form of superior dispersion characteristics in aqueous electrode active material mixtures, as well as beneficial effects in terms of lowered ESR and reduced gas production compared to standard binders in the art, were previously completely unappreciated.

For the purposes of the following discussion, the term “supercapacitor” refers to devices that also go by the names ultra capacitor, electrochemical double layer capacitor (EDLC), and electrochemical capacitor, pseudocapacitors, hybrid supercapacitors, amongst others. All such devices are contemplated as devices within the scope of the present disclosure. Additionally, although the invention described herein has been developed primarily for supercapacitors and will be described with reference to that application, it will be appreciated that the binders described herein may also be suitable for other energy storage devices such as batteries. All such devices are considered energy conversion or storage devices in the disclosure herein.

As used herein, the term “electrode active layer” refers to a layer comprising materials that are active in the storage and/or conversion of chemical and/or electrical energy. Electrode active layers comprise at least one active material and a binder. Conductive surfaces acting as current collectors form part of overall composite electrodes, of which the electrode active layers are one part.

As used herein, the term “substantially” refers to within +/−5%, 4% 3%, 2% or 1%.

### Electrode Active Layer

Described herein is an electrode active layer for an energy conversion or storage device, comprising an active material; and a binder comprising a salt of a sulfonated polymer. The sulfonate group has formula —SO₃ and as a functional group has structure, where R is an organic group:

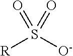

As used herein, the term “sulfonate” refers to a sulfonate anion functional group, being the deprotonated form of sulfonic acid. It will be understood that any references to sulfonates herein implicitly refer to sulfonate salts (as opposed to esters), the salts being distinguished by comprising a non-hydrogen cation as counterion to the negative charge carried by the sulfonate anion. Sulfonated polymers are those containing a sulfonate functional group. For the avoidance of doubt, sulfonic acid polymers in their acid form are not within the scope of the term sulfonate salt.

In one embodiment, the binders herein comprise non-perfluorinated sulfonate polymers, which refers to sulfonate polymers in which every hydrogen that would be attached to a carbon in the organic polymer has been replaced by a fluorine. In such cases, it may be appreciated that fluorination of some, but not all, organic carbons in the polymer may be tolerated. In another embodiment, the binders herein may comprise non-fluorinated sulfonate polymers. By “non-fluorinated”, it is meant that the sulfonate polymers contain no fluorine atoms at all. In one embodiment, the binders herein are devoid of perfluorinated polymers and perfluorinated monomers, whether sulfonated or not. In one embodiment, the binders herein are devoid of fluorinated polymers and fluorinated monomers, whether sulfonated or not.

In some embodiments, the binders herein comprise non-chemically crosslinked sulfonate polymers. By “non-chemically crosslinked”, it is meant that the polymers do not contain chemical, i.e., covalent, cross-links, and no chemical, i.e., covalent, cross-linking agent is used.

It will be appreciated that cations, such as metal cations, may have a physical (e.g., ionic) cross-linking effect in negatively charged polymers. Physical cross-links of this kind are acceptable in the polymers comprising the binders herein.

The sulfonated polymer may have any suitable structure. In one embodiment, the sulfonated polymer is derived from at least some monomers containing sulfonate groups. In other embodiments, the polymer is post-synthetically modified to contain sulfonate groups, such as by reaction of other functional groups in the polymer to form sulfonate groups. The skilled person will be familiar with methods for producing a variety of sulfonate polymers, such as described in Khomein et al., (2021) Sulfonated aromatic polymer as a future proton exchange membrane: A review of sulfonation and crosslinking methods, Renewable and Sustainable Energy Reviews, 137, the contents of which are incorporated herein by cross-reference, or may utilise commercially available sulfonate polymers such as poly(4-styrenesulfonic acid) solution, 2-propene-1-sulfonic acid (allyl sulfonic acid), or 2-acrylamido-2-methyl-1-propanesulfonic acid, each of which can be reacted with a base, such as a hydroxide or carbonate, to form salts thereof, or poly(sodium 4-styrenesulfonate), vinyl sulfonic acid, sodium salt, or 2-methyl-2-propene-1-sulfonic acid sodium salt, all of which may be obtained from Sigma Aldrich.

In one embodiment, the sulfonated polymer is derived from monomers comprising one sulfonate group per monomer. In one embodiment, the sulfonated polymer is derived from monomers comprising a substituted C₂ to C₆ linear or branched alkene. The alkene preferably comprises a single vinyl (C═C) group. In one embodiment, the substituted C₂ to C₆ linear or branched alkene is a C₂ alkene (C═C), a C₃ alkene (C═C—C), a C₄ alkene (C═C—C—C), (C—C═C—C), (C═C(C)—C), etc., a Cₛ alkene or a C₆ alkene (hydrogens and substituents not shown). The substitution may be on any carbon in the C₂ to C₆ linear or branched alkene.

Although the C₂ to C₆ linear or branched alkene may comprise any suitable substituents, in one embodiment, the substituents comprise one or more of: —R₁SO₃—, —R₁ArSO₃⁻, —C(═O)NHR₁SO₃⁻, —C(═O)NHR₁ArSO₃⁻, —C(═O)NHArR₁SO₃, —ArR₁SO₃⁻, or —ArSO₃; where R₁═C₁ to C₆ linear or branched alkyl group or a bond and Ar=aryl group. In one embodiment, the aryl group is a phenyl group.

In one embodiment, the monomer is H₂C═CH—R₁SO₃⁻, H₂C═CH—R₁ArSO₃⁻, H₂C═CH—ArR₁SO₃⁻, or H₂C═CH—ArSO₃⁻, where R₁═C₁ to C₆ linear or branched alkyl group or a bond and Ar=aryl group. In one embodiment, the monomer is (C₃H₅)—R₁SO₃⁻, (C₃H₅)—R₁ArSO₃⁻, (C₃H₅)—ArR₁SO₃⁻, or (C₃H₅)—ArSO₃⁻, where R₁═C₁ to C₆ linear or branched alkyl group or a bond and Ar=aryl group. In another embodiment, the monomer is H₂C═CH—CH₂—R₁SO₃⁻, H₂C═CH—CH₂—R₁ArSO₃, H₂C═CH—CH₂—ArR₁SO₃⁻, or H₂C═CH—CH₂—ArSO₃⁻, where R₁═C₁ to C₆ linear or branched alkyl group or a bond and Ar=aryl group. In one embodiment, the monomer is (C₄H₇)—R₁SO₃⁻, (C₄H₇)—R₁ArSO₃⁻, (C₄H₇)—ArR¹SO₃⁻, or (C₄H₇)—ArSO₃⁻, where R₁═C₁ to C₆ linear or branched alkyl group or a bond and Ar=aryl group.

In another embodiment, the monomer is H₂C═CH—CH₂—R₁SO₃⁻, H₂C═CH—CH₂—R₁ArSO₃, H₂C═CH—CH₂—ArR₁SO₃⁻, or H₂C═CH—CH₂—ArSO₃⁻, where R₁═C₁ to C₄ linear or branched alkyl group or a bond and Ar=phenyl group. In another embodiment, the monomer is H₂C═CH—R₁SO₃, H₂C═CH—R₁ArSO₃⁻, H₂C═CH—ArR₁SO₃⁻, or H₂C═CH—ArSO₃⁻, where R₁═C₁ or C₂ linear alkyl group or a bond and Ar=phenyl group.

In a further embodiment, the monomer is —C(═O)NHR₁SO₃⁻, —C(═O)NHR₁ArSO₃⁻, or —C(═O)NHArR₁SO₃⁻, where R₁═C₁ to C₆ linear or branched alkyl group or a bond and Ar=phenyl group. In a further embodiment, the monomer is —C(═O)NHR₁SO₃⁻, where R₁═C₃₋₅ branched alkyl group and Ar=phenyl group, or where R₁=—C(CH₃)₂CH₂— and Ar=phenyl group.

In one embodiment, the sulfonate-bearing groups in the polymer are benzenesulfonate groups, such as shown below:

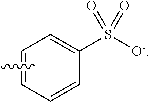

In one embodiment, the sulfonated polymer is derived from monomers containing one benzenesulfonate group per monomer. In one embodiment, the sulfonated groups in the polymer comprise benzenesulfonate groups.

In one embodiment, the binder comprises a salt of poly(styrene sulfonate), poly(vinyl sulfonate), poly(2-acrylamido-2-methyl-1-propanesulfonate), poly(2-propene-1-sulfonate), or poly(2-methyl-2-propene-1-sulfonate). In one embodiment, the binder consists of a salt of poly(styrene sulfonate), poly(vinyl sulfonate), poly(2-acrylamido-2-methyl-1-propanesulfonate), poly(2-propene-1-sulfonate), or poly(2-methyl-2-propene-1-sulfonate). In one embodiment, the binder comprises a salt of poly(styrene sulfonate). In one embodiment, the binder comprises a salt of poly(2-acrylamido-2-methyl-1-propanesulfonate). In one embodiment, the binder comprises a salt of poly(2-propene-1-sulfonate). In one embodiment, the binder comprises a salt of poly(2-methyl-2-propene-1-sulfonate). In one embodiment, the binder does not comprise a salt of poly(vinyl sulfonate).

The salt of the sulfonated polymer may comprise any suitable cation. In one embodiment, the polymers comprise a Group I metal cation, a Group II metal cation, a transition metal cation, or an ammonium-based cation as the counterion. Salts of sulfonated polymers may comprise one or more counterions selected from a Group I or Group II metal cation. Such embodiments may be favoured where water solubility for processing is highly desirable. Such cations include lithium, potassium, sodium, caesium, magnesium, and calcium cations. In one embodiment, the salt of the sulfonated polymer may comprise Group I metal cations. In one embodiment, the salt of the sulfonated polymer may comprise Group II metal cations. In some embodiments, the salt of the sulfonated polymer comprises sodium, lithium, magnesium or calcium cations, such as is a sodium salt, a lithium salt, a magnesium salt, or a calcium salt. In some embodiments, a mixture of different cations may be used as counterions for the same polymer chain, such as a mixture of Li and Na, or a mixture of Ca and Mg cations. Other cation combinations will be apparent to persons of skill in the art. In other embodiments, the salt of the sulfonated polymer may comprise one or more transition metal cations, such as zinc, iron, and/or nickel cations. In one embodiment, the binder consists of a single salt of a sulfonated polymer. In another embodiment, the binder comprises a mixture of two or more different salts of sulfonated polymers.

In some embodiments, the cation may be chosen to harmonise with the ion system of the energy storage and/or conversion device. Ion homogeneity between the electrochemically active materials in the device and the binder may prevent competing redox reactions. By way of non-limiting example only, hybrid Li-ion/supercapacitor devices may comprise lithium salts of the sulfonated polymer, and hybrid K-ion/supercapacitor devices may comprise potassium salts of the sulfonated polymer. Other energy storage and conversion devices utilising sodium, zinc, iron or nickel etc. may utilise sodium, zinc, iron or nickel etc. salts of the sulfonated polymer.

In one embodiment, the salt of the sulfonated polymer may comprise ammonium-based cations. Such cations are often used as the cation component in EDLCs and include, but are not limited to, primary, secondary, tertiary or quaternary alkylammonium cations and their substituted equivalents, such as the 2-(methylthio)ethylammonium cation. Quaternary ammonium cations are known to be particularly stable at the typical operating voltages of supercapacitors. Quaternary ammonium cations are the most common used cations in EDLC electrolytes and are suitable for use as cations in the salts in the binders described herein. Suitable quaternary ammonium cations include, but are not limited to, tetramethylammonium, methyltriethylammonium, tetraethylammonium, tetrapropylammonium, or tetrabutylammonium cations. In one embodiment, the quaternary ammonium cation has the chemical structure:

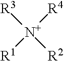

where R¹, R², R³ and R⁴ are each alkyl substituents. In one embodiment, R¹, R², R³ and R⁴ are each, independently, a C₁-C₇ straight or branched alkyl chain. In one embodiment, R¹, R², R³ and R⁴ are independently, a C₁-C₄ straight or branched alkyl chain. In one embodiment, R¹, R², R³ and R⁴ are independently, a C₁-C₂ straight alkyl chain. In one embodiment, R¹ is different to at least one of R², R³ and R⁴. In an embodiment, R¹, R², R³ and R⁴ are different to each other.

In another embodiment, the salt of the sulfonated polymer may comprise nitrogen-containing heterocyclic cations. Suitable examples are spiro-bis-pyrrolidinium (SBP), N,N-dimethylpyrrolidinium, N-methyl-N′-propylpyrrolidinium, N,N′-dimethylimidazolium, N-methyl-N′-ethylimidazolium and N-methyl-N′-propylimidazolium. In one embodiment, the quaternary ammonium cation is a nitrogen-containing heterocyclic cation having the chemical structure:

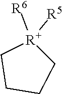

where R⁶ and R⁶ are each alkyl substituents. In an embodiment, R⁵ and R⁶ each independently comprise a C₁-C₇ straight or branched alkyl chain. In one embodiment, R⁵ is different to R⁶.

The sulfonated polymer described herein may have any suitable average molecular mass, referring to the average molecular mass of each polymer chain. In one embodiment, an average molecular mass of the polymer is from about 20,000 g/mol to about 2,000,000 g/mol, or of from 20,000 to 100,000 g/mol, or of from 70,000 g/mol to 125,000 g/mol, or of from 85,000 g/mol to 140,000 g/mol, or of from 100,000 g/mol to 500,000 g/mol, or of from 250,000 g/mol to 750,000 g/mol, or of from 500,000 g/mol to 1,000,000 g/mol, or of from 1,000,000 g/mol to 1,500,000 g/mol, or of from 1,250,000 g/mol to 2,000,000 g/mol, or of from 70,000 g/mol to 1,250,000 g/mol, or of 50,000, 60,000, 70,000, 75,000, 80,000, 90,000, 100,000, 110,000, 120,000, 130,000, 140,000, 150,000, 250,000, 500,000, 1,000,000, 1,250,000, 1,500,000, 1,750,000 or 2,000,000 g/mol. This molecular mass may be the molecular mass of the protonated form of the polymer before it is converted to a salt. Alternatively, in other embodiments, an average molecular mass of the polymer salt be from about 50,000 g/mol to about 2,000,000 g/mol or of from 50,000 to 10,000 g/mol, or of from 70,000 g/mol to 125,000 g/mol, or of from 85,000 g/mol to 140,000 g/mol, or of from 100,000 g/mol to 500,000 g/mol, or of from 250,000 g/mol to 750,000 g/mol, or of from 500,000 g/mol to 1,000,000 g/mol, or of from 1,000,000 g/mol to 1,500,000 g/mol, or of from 1,250,000 g/mol to 2,000,000 g/mol, or of from 70,000 g/mol to 1,250,000 g/mol, or of 50,000, 60,000, 70,000, 75,000, 80,000, 90,000, 100,000, 110,000, 120,000, 130,000, 140,000, 150,000, 250,000, 500,000, 1,000,000, 1,250,000, 1,500,000, 1,750,000 or 2,000,000 g/mol. In such embodiments, the molecular mass includes the counterion of the salt once the polymer has been converted to a salt. In one embodiment, the molecular mass of the polymer is of from about 70,000 g/mol to about 100,000 g/mol. In one embodiment, the molecular mass of the polymer salt is of from about 70,000 g/mol to about 100,000 g/mol. In one embodiment, the molecular mass of the polymer salt is of from about 100,000 g/mol to about 1,000,000 g/mol. In one embodiment, the molecular mass of the polymer salt is of from about 70,000 g/mol to about 900,000 g/mol.

The binder may comprise any suitable wt % of the salt of the sulfonated polymer. In some embodiments, the binder is pure salt of the sulfonated polymer, such that the binder comprises ~100 wt %, or at least 99%, 98%, 95%, or 90% of the salt of the sulfonated polymer.

In another embodiment, the binder comprises a copolymer derived from two or more different sulfonated monomers or one or more sulfonated monomers and at least one other monomer. The nature of the copolymer is not particularly limited, but random copolymers may be preferred over block copolymers.

Where the copolymer comprises two or more different sulfonated monomers, each monomer may be as described above. Alternatively, other sulfonated monomers may be utilised, such as 2-acrylamido-2-methyl-1-propanesulfonate (PAMP).

Where the copolymer comprises at least one other monomer, the at least one other monomer may be sulfonated or may be non-sulfonated. The at least one other monomer may be non-fluorinated. The at least one other monomer may be non-perfluorinated. In one embodiment, the at least one other monomer comprises an optionally substituted C₂ to C₆ cyclic, linear or branched alkene, such as a C₂ alkene (C═C), a C₃ alkene (C═C—C), a C₄ alkene (C═C—C—C), (C—C═C—C), (C═C(C)—C), etc., a Cₛ alkene or a C₆ alkene (hydrogens and substituents not shown). The optional substituent may be a phenyl group, a C₁ to C₆ linear or branched alkyl group, a carboxylic acid, a carbonyl, or an amide. In one embodiment, the at least one other monomer is a substituted alkene, such as 1,2-difluoroethylene, or tetrafluoroethylene, or maleic acid or a salt thereof. In one embodiment, the at least one other monomer is styrene and butadiene. In one embodiment, the at least one other monomer is an acrylic monomer, such as acrylic acid or a salt thereof, methacrylic acid or a salt thereof, or butylacrylic acid or a salt thereof. In one embodiment, the C₂ to C₆ linear or branched alkene is unsubstituted. In one embodiment, the at least one other monomer is a cyclic anhydride with a C═C bond, such as maleic anhydride. In one embodiment, the sulfonated monomers comprise one sulfonate group per monomer, optionally one benzenesulfonate group per monomer, and the at least one other monomer is devoid of sulfonate groups.

In one embodiment, when the binder comprises a copolymer derived from two or more different sulfonated monomers or one or more sulfonated monomers and at least one other monomer, the copolymer comprises at least 30 wt %, at least 40 wt %, at least 50 wt %, at least 60 wt %, at least 70 wt %, at least 80 wt %, at least 90 wt %, at least 95 wt %, or at least 99 wt % of the sulfonated monomer, or of from 30 to 99 wt %, or of 30 to 50 wt %, or of 50 to 75 wt %, or of 70 to 90 wt %, or of 60 to 99 wt % of the sulfonated monomer, or of 30, 40, 50, 60, 70, 80, 90, 95, or 99 wt % of the sulfonated monomer, at least 30 mol %, at least 40 mol %, at least 50 mol %, at least 60 mol %, at least 70 mol %, at least 80 mol %, at least 90 mol %, at least 95 mol %, or at least 99 mol % of the sulfonated monomer, or of from 30 to 99 mol %, or of 30 to 50 mol %, or of 50 to 75 mol %, or of 70 to 90 mol %, or of 60 to 99 mol % of the sulfonated monomer, or of 30, 40, 50, 60, 70, 80, 90, 95, or 99 mol % of the sulfonated monomer.

In one embodiment, the binder comprises a mixture of a salt of a sulfonated polymer and at least one other polymer, such as a polymer produced from the at least one other monomer described above. In one embodiment, the at least one other polymer may be PVDF, PTFE, SBR or an acrylic-based polymer. In such embodiments, the mixture may comprise at least 30 wt %, at least 40 wt %, at least 50 wt %, at least 60 wt %, at least 70 wt %, at least 80 wt %, at least 90 wt %, at least 95 wt %, or at least 99 wt % of the sulfonated polymer or salt thereof, or of from 30 to 99 wt %, or of 30 to 50 wt %, or of 50 to 75 wt %, or of 70 to 90 wt %, or of 60 to 99 wt % of the sulfonated polymer or salt thereof. In one embodiment, the binder herein comprises a salt of a sulfonated polymer in admixture or in a blend with a conventional compound used as a binder in energy storage devices. Conventional compounds suitable for use in admixture with the salts of sulfonated polymers as described herein or in a blend include, but are not limited to, PVDF, PTFE, SBR or an acrylic-based binder.

In one embodiment, the binder herein is fully soluble in water, or has a solubility of at least 0.02 g/mL in water. In one embodiment, the sulfonated polymer comprising the binder herein is fully soluble in water, or has a solubility of at least 0.1 g/mL in water.

In one embodiment, the binder herein has a pH of about 7, or of from 6 to 8, such as of from 6.5 to 7.5, or of from 6.8 to 7.2, or of about 6, 6.25, 6.5, 6.75, 7.0, 7.25, 7.5, 7.75 or 8. In some embodiments, the pH of the binder may be adjusted using a base, such as a metal hydroxide, or an acid, such as tetrafluoroboric acid, TFSI acid, or methylsulfonic acid.

The electrode active layer for an energy conversion or storage device described herein comprises an active material. Electrode “active materials” may include, but are not limited to, cathode materials, anode materials, and electrochemically active materials, which may include solvents, additives, and/or electrolyte salts depending on the application.

The active material in the electrode active layers described herein is not particularly limited. In one embodiment, the active material is carbon based. In one embodiment, the active material is an amorphous carbon, carbon nanotubes, graphene, graphene oxide, reduced graphene oxide, or an activated carbon.

Activated carbon has a high surface area and porosity that make it particularly suitable for use in EDLC supercapacitor devices, where their high surface area and porous nature increases the effective area of the capacitor plate and therefore the maximum achievable capacitance. Accordingly, in one embodiment, the active material is an activated carbon. In one embodiment, the activated carbon has a surface area of at least 1200 m²/g. In another embodiment the carbon based material has a surface area of at least 400 m²/g. In an embodiment, activated carbons include activated carbons with a surface area of between 1200 and 3000 m²/g. In another embodiment, the activated carbons have a particle size D50 between 3 μm and 10 μm and a D10>1 μm and a D90<30 μm. In another embodiment, the activated carbon is a microporous carbon where more than 50% of the pore volume is less than 2 nm in in size. Examples of commercially available microporous activated carbons suitable for use as active materials herein are MSP20 (Kansai Coke), MSC-30 (Kansai Coke), FAR01X (Kansai Coke), YP-80F (Kuraray), RP-25 (Kuraray), RP-20 (Kuraray), NY1151 (Kuraray Chemical Co., Ltd), NK261H (Kuraray), HDLC 20B STUW (Haycarb PLC), DLC 30 (Haycarb PLC), DLC 20P (Haycarb PLC), HCE-201 (Haycarb PLC), HCE-202 (Haycarb PLC), ACS20 (China Steel Chemical Corporation), ACS25 (China Steel Chemical Corporation), Yec-200E (IHUAN Carbon), YEC-8A (IHUAN Carbon), YEC-8B (IHUAN Carbon), Y-Carbon (Y-Carbon Inc.), ZL-302 (Huzhou Sensheng Activated Carbon Co., Ltd), MCSP 2005 (Calgon Mitsubishi Chemical Corporation), MCSP 1805A (Calgon Mitsubishi Chemical Corporation), and MCSP 1805-1 (Calgon Mitsubishi Chemical Corporation).

In another embodiment, the activated carbon can be classified as a mesoporous carbon where more than 50% of the pore volume has a pore size greater than 2 nm. Examples of commercially available mesoporous carbons suitable for use as active materials herein are P2-15 (EnerG2), MSA-20 (Kansai Coke and Chemicals), YP-50F (Kuraray), NY1251H (Kuraray), YPS (Kuraray), ACS15 (China Steel Chemical Corporation), TDA 60 (TDA Research), SO-15A (TDA Research), and ACC (Xiamen All Carbon Corporation).

In other embodiments, the active material may be oxide based, such as is a transition metal oxide. These oxide materials are often used as cathode active materials in batteries or supercapacitors and sometimes as the anodes. Examples of transition metal oxides may include NiO, ZnO, RuO₂, MnO₂, CO₃O₄, WO₃, V₂O₅, LiTiO₄ and mixed-metal oxides such as XCo₂O₄ (X=Mn, Cu, Ni), and AMoO₄ (A=Co, Mn, Ni, Zn). Other cathode materials typically used in batteries, hybrid capacitors or pseudo capacitors include layered oxides, oxoanions, polyanion and Prussian Blue and its analogues LiCoO₂, LiMn₂O₄, LiFePO₄, Lithium Nickel Manganese Cobalt oxides (NCM) generally written as LiNiMnCoO₂, Lithium nickel cobalt aluminium oxides (NCA) generally written as LiNiCoAIO₂, Lithium nickel cobalt manganese aluminium oxide (NCMA) LiNiCoMnAIO₂, LiNiO₂, NaFeMnO₂, NaMnMgO₂, NaNiMnMgO₂, KMnO₂, KCoO₂, etc.

In one embodiment, carbon based anode battery type materials can be used as the active material. In another embodiment, the active material is graphite, a hard carbon or a soft carbon. In one embodiment, the anode may be silicon-based.

In certain embodiments, the active material is a composite of a carbon-based and oxide-based system, such as a graphene oxide or an activated carbon/metal oxide composite. Suitable commercial sources of active materials such as activated carbons will be known to those of skill in the art.

The electrode active layer herein may have any suitable thickness. In one embodiment, the electrode active layer has a thickness, once dried, of from 5 μm to 200 μm, or of from 5 μm to 100 μm, of from 5 μm to 80 μm, of from 5 μm to 60 μm, of from 5 μm to 50 μm.

The binder may be present in any suitable amount in the electrode active layer. The amount of binder in the electrode active layer can be calculated as a percentage by weight of all the solid components in the electrode active layer without electrolyte. In one embodiment, the binder is present in an amount of from 1 to 30 wt % of the electrode active layer, or of from 1 to 10 wt %, or of from 5 to 20 wt %, or of from 10 to 25 wt %, or of from 15 to 30 wt %, or of from 2 to 20 wt %, or of 1, 2, 3, 4, 5, 6, 7, 8, 9, 10, 12.5, 15, 17.5, 20, 25, or 30 wt % of the electrode active layer. The wt % may be calculated as [mass_{binder}/(mass_{binder}+mass_{active material}+mass_{other solids, if present})]×100.

In one embodiment, the electrode active layer further comprises a conductive material. Conductive materials are generally required where the active material has insufficient conductivity in the energy storage/conversion device, or where it is desired to increase the conductivity within the electrode active layer. In some embodiments, use of a carbon-based active material such as activated carbon may require addition of a conductive material.

The nature of the conductive material is not particularly limited. In some embodiments, the conductive material is a conductive carbon, such as a carbon black, graphite, graphene, carbon nanotubes, or the like. In one embodiment, the conductive material is a conductive carbon, or is a carbon black. In one embodiment, the carbon black has a BET (N₂) surface area of from about 100 to 500 m²/g. In another embodiment, the carbon black has a sub-micron primary particle size between 10 nm to 100 nm. Carbon black particles often aggregate and require high shear to disperse them sufficiently in an electrode slurry. Suitable commercial sources of conductive materials such as conductive carbons will be known to those of skill in the art, and include Printex carbon black such as L6 (Orion Carbons), PRINTEX© kappa 100 (Orion Engineered Carbons), PRINTEX® XE2 (Orion Engineered Carbons), ENSACO 150G (IMERYS), ENSACO 210G (IMERYS), ENSACO 250G (IMERYS), ENSACO 250F (IMERYS), ENSACO 260G (IMERYS), ENSACO 350G (IMERYS), Super C65 (IMERYS), LITX® HP (CABOT), LITX300 (CABOT), LITX200 (CABOT), VXC72R (CABOT), BP 700 (CABOT), BP 2000 (CABOT), SC2A (CABOT), TPX1278 (CABOT), Lump Black (Degussa), Ketjenblack EC300J (Akzo Noble), Ketjenblack EC600JD (Akzo Noble), E-MM-198G (Timcal), Super P (Timcal).

### Composite Electrode

Described herein is a composite electrode, comprising an electrode active layer on a conductive surface, wherein the electrode active layer comprises an active material and a binder comprising a salt of a sulfonated polymer.

Also described herein is use of a salt of a sulfonated polymer as described herein as a binder in an electrode active layer of a composite electrode.

The electrode active layer in the composite electrode is in contact with a current collector, generally being manufactured in situ so as to maximise adhesion of the electrode active layer on the current collector. In such embodiments, the binder and active material are processed into an electrode slurry in a solvent, and the electrode slurry is applied to the current collector using any suitable application means. The solvent is then driven off through a drying process, leaving the electrode active layer comprising the binder and active material on the current collector.

Suitable methods for producing composite electrodes are described elsewhere herein. Although the current collector is not particularly limited, and can generally comprise any conductive material, in some embodiments, the current collector is a metal foil. Suitable metal foils may include aluminium or copper foil, although other metal foils may also be suitable.

### Devices

Also described herein is an energy storage device comprising a composite electrode as described above. Although the energy storage device is not particularly limited, in one embodiment, the energy storage device is a supercapacitor or battery. In one embodiment, the energy storage device is a supercapacitor. The supercapacitor may be a prismatic supercapacitor or a cylindrical supercapacitor. In one embodiment, the energy storage device is a battery. In one embodiment, the battery is an Li-ion battery, a Na-ion battery, a K-ion battery, an Al-ion battery, or a Ca-ion battery. In one embodiment, the energy storage device is a supercapacitor-battery hybrid. In one embodiment, the hybrid device is a Li-ion/supercapacitor hybrid, a K-ion/supercapacitor hybrid, or a Na-ion/supercapacitor hybrid, or an AI-ion/supercapacitor hybrid, or a Ca-ion/supercapacitor hybrid.

It is possible to use the binders of the present invention to create either symmetric or asymmetric energy storage devices. In a symmetric device, each electrode utilises the same binder. In an asymmetric device, the binder compositions are varied such that the first and second electrodes have different binders. Asymmetric electrodes allow for higher voltage and higher energy density in supercapacitors. The higher voltage operation is possible by varying the energy density on each electrode to ensure that the voltage drop across the interface of the electrode is optimal for energy access and stability of the electrode. Batteries are intrinsically asymmetric devices, as the chemistries of each electrode are optimised for either oxidation or reduction. In such cases, the binder is selected to be stable under the electrochemical environment at each electrode.

Accordingly, in one embodiment, the energy storage device comprises at least two composite electrodes, and each composite electrode comprises the same binder. This embodiment is particularly suitable for supercapacitors.

In another embodiment, the energy storage device comprises two composite electrodes, wherein each composite electrode comprises a different binder. This embodiment is suitable for supercapacitors, batteries and hybrid devices.

In the energy storage and conversion devices herein, the space between electrodes generally contains an electrolyte, which is frequently solvent comprising a dissolved salt. In supercapacitors, the electrolyte is a source of ions required to form the double layer on the surface of the carbon-containing electrode active layer, but also allows ionic conductance between opposing electrodes. The electrolyte in the devices herein is not particularly limited. Persons of skill in the art will be familiar with electrolytes suitable for use in energy storage and conversion devices and will be familiar with suitable electrolytes for use in the devices described herein. In one embodiment, the electrolyte comprises an ionic liquid, or an organosulfur compound such as sulfolane, an organic carbonate such as propylene carbonate, or a gamma-butyrolactone and at least one organic salt such as an organic tetrafluoroborate salt.

In some energy conversion and storage devices, a separator may be required to isolate the electrodes physically and prevent electrical shorting. In supercapacitors, the separator is generally a porous material, such as a porous polymer, which permits storage of electrolyte and transfer of ions from anode to cathode during charge and discharge. The separators herein are not particularly limited, and persons of skill in the art will be familiar with suitable separators for use in the devices herein. In one embodiment, the separator is made with a polymer such as high density polyethylene, polypropylene, PTFE, PET or PTFE. In another embodiment, the separator is made from fibres, such as cellulose fibres, glass fibres or Aramid fibres.

### Methods for Producing Slurries and Electrodes

Described herein is an electrode slurry for producing an electrode active layer, the electrode slurry comprising an active material, a binder comprising a salt of a sulfonated polymer, and a solvent.

The electrode slurry may comprise any suitable amount of solvent, such as an amount of solvent sufficient to disperse the active material and to achieve a spreadable viscosity of the electrode slurry on a conductive surface. In one embodiment, the electrode slurry comprises from about 60 to about 95 wt % solvent, or of from 60 to 80 wt %, or 75 to 90 wt %, or 80 to 95 wt % of solvent, or 60, 65, 70, 75, 80, 85, 90 or 95 wt % of solvent. The solvent is not particularly limited herein, but for environmental reasons, water is the preferred solvent. In one embodiment, the solvent is an organic solvent such as methanol, ethanol or X. In another embodiment, the solvent is water. In another embodiment, the solvent is a mixture of methanol or ethanol in water. Other suitable solvents will be apparent to those of skill in the art.

The electrode slurry herein may comprise any suitable percent by weight binder on a solids basis. In one embodiment, the electrode slurry herein comprises from 1 to 30 wt % of binder on a solids basis, or of from 1 to 10 wt %, or of from 5 to 20 wt %, or of from 10 to 25 wt %, or of from 15 to 30 wt %, or of from 2 to 20 wt %, or of 1, 2, 3, 4, 5, 6, 7, 8, 9, 10, 12.5, 15, 17.5, 20, 25, or 30 wt % of binder on a solids basis.

The active material of the slurry may be the same as the active material of the electrode active layer as described elsewhere herein.

The electrode slurry herein may comprise any suitable percent by weight of active material on a solids basis. In one embodiment, the electrode slurry herein comprises from 50 to 99 wt % of active material on a solids basis, or of from 50 to 75 wt %, or of from 70 to 90 wt %, or of from 80 to 99 wt %, or of from 55 to 85 wt %, or of 50, 55, 60, 65, 70, 75, 80, 85, 90, 95 or 99 wt %.

In one embodiment, the electrode slurry is a substantially homogenous dispersion of the active material. In one embodiment, the electrode slurry comprises a substantially homogeneous dispersion of active material particles. In one embodiment, the electrode slurry comprises a substantially homogeneous dispersion of active material particles and conductive particles. In one embodiment, the electrode slurry is substantially devoid of agglomerates and aggregates of active and/or conductive material particles. In one embodiment, the active material has a particle size distribution of from D10 >1 μm to D90<20 μm and 3 μm<D50<10 μm, or has particle size distribution of from D10 >1 μm and D90<50 μm and a 5 μm<D50 <20 μm.

The electrode slurry may comprise any suitable percent by weight of conductive material on a solids basis. In one embodiment, the electrode slurry comprises from 5 to 25 wt % of conductive material on a solids basis, or of from 5 to 10 wt %, or of 7 to 15 wt %, or of 10 to 20 wt %, or of 15 to 25 wt %, or of 10 to 25 wt %, or of 5, 10, 15, 20 or 25 wt % of conductive material on a solids basis.

The electrode slurry may be synthesised using any suitable technique in the art. In one embodiment, the binder is first dispersed in a solvent, such as water, and the active material is then added and the resultant mixture blended. Blending conditions may include using a magnetic stirrer bar or other mechanical mixing apparatus, and the mixing may be for any suitable time, such as a period of from 1 min to 48 h, or of 1 h to 24 h, or of from 5 min to 1 h, or of from 1 h to 36 h. In some embodiments, if conductive material is used, the conductive material may be added after mixing/blending of the active material, and the mixture blended for a further period of from 1 min to 48 h, or of 1 h to 24 h, or of from 5 min to 1 h, or of from 1 h to 36 h.

In one embodiment, the mixture is dispersed using a high shear mixer for a period of from 2 to 30 s, or of from 30 s to 5 min, or of from 2 min to 10 min, or of from 2 s to 30 min. High shear dispersion may be suitably performed after the initial mixing or blending step.

In other embodiments, the active material and conductive material are dispersed in the binder/solvent mixture, such as water, at the same time, and subjected to a single mixing step and an optional subsequent high shear dispersal step.

Also described herein is a method of making an electrode active layer, comprising applying an electrode slurry as described herein to a current collector; and drying the electrode slurry to remove the solvent.

The current collector is not particularly limited, and can generally comprise any conductive material. In some embodiments, the current collector is a metal foil. Suitable metal foils may include aluminium or copper foil, although other metal foils may also be suitable. The current collector may have any suitable thickness. In some embodiments, the current collector is a metal foil having a thickness of 1 μm to 100 μm.

The step of applying may comprise any suitable technique known in the art. In one embodiment, the step of applying comprises using screen printing, gravure printing, ink jet printing, slot die printing, K-bar coating, or the like to apply the electrode slurry on the current collector. In one embodiment, the electrode slurry is applied in a thin layer, such as in a layer of thickness 1 μm to 100 μm, or of thickness 10 μm to 1000 μm, on the current collector. In one embodiment, the layer is applied at substantially the same thickness across the current collector.

The step of drying may comprise any suitable technique known in the art. In one embodiment, the electrode slurry on the current collector is dried in a vacuum oven, such as at a temperature of from 80 to 160° C., for a period of from 5 min to 24 h and under a reduced pressure of less than 200 mbar. During drying, the solvent evaporates to leave the binder and active material, including any conductive material, on the current collector. In some embodiments, ~100% of the solvent is removed during the drying step, or at least 90%, 95% or 99% of the solvent is removed during the drying step.

### EMBODIMENTS

The following Embodiments are disclosed herein:
Embodiment 1. An electrode active layer for an energy conversion or storage device, comprising:
   an active material; and
   a binder comprising a salt of a sulfonated polymer.
Embodiment 2. The electrode active layer of Embodiment 1, wherein the sulfonated polymer comprises substituted C₂ to C₆ linear or branched alkene monomers.
Embodiment 3. The electrode active layer of Embodiment 1 or Embodiment 2, wherein the sulfonated polymer comprises substituted C₂ to C₆ linear or branched alkene monomers, and the substituted C₂ to C₆ linear or branched alkene comprises, as a substituent, one or more of: —R₁SO₃⁻, —R₁ArSO₃⁻, —ArR₁SO₃⁻, —ArSO₃— or —C(═O)NHR₁SO₃⁻, —C(═O)NHR₁ArSO₃⁻, —C(═O)NHArR₁SO₃⁻;
   wherein R₁═C₁ to C₆ linear or branched alkyl group or a bond; and Ar=aryl group.
Embodiment 4. The electrode active layer of Embodiment 3, wherein Ar=a phenyl group.
Embodiment 5. The electrode active layer of any one of the preceding Embodiments, wherein the sulfonated polymer comprises benzenesulfonate groups.
Embodiment 6. The electrode active layer of any one of the preceding Embodiments, wherein the sulfonated polymer comprises monomers comprising one sulfonate group per monomer, optionally one benzenesulfonate group per monomer.
Embodiment 7. The electrode active layer of any one of the preceding Embodiments, wherein the sulfonated polymer comprises monomers selected from: styrene sulfonate, vinyl sulfonate, 2-acrylamido-2-methyl-1-propanesulfonate, 2-propene-1-sulfonate, or 2-methyl-2-propene-1-sulfonate.
Embodiment 8. The electrode active layer of Embodiment 7, wherein the sulfonated polymer comprises styrene sulfonate monomers.
Embodiment 9. The electrode active layer of any one of the preceding Embodiments, wherein the salt of the sulfonated polymer comprises one or more counterions selected from: a Group I metal cation, a Group II metal cation, a transition metal cation, a quaternary ammonium cation, or a nitrogen-containing heterocyclic cation.
Embodiment 10. The electrode active layer of any one of the preceding Embodiments, wherein the salt of the sulfonated polymer comprises one or more counterions selected from lithium, potassium, sodium, caesium, magnesium, and calcium cations.
Embodiment 11. The electrode active layer of any one of the preceding Embodiments, wherein the salt of the sulfonated polymer comprises sodium, potassium, lithium, magnesium and/or calcium cations.
Embodiment 12. The electrode active layer of any one Embodiments 1 to 9, wherein the salt of the sulfonated polymer comprises one or more counterions selected from an optionally substituted alkylammonium cation, such as tetramethylammonium, tetraethylammonium, tetrapropylammonium, or tetrabutylammonium, or a 2-(methylthio)ethylammonium cation, or a nitrogen-containing heterocyclic cation such as spiro-bis-pyrrolidinium (SBP), N,N-dimethylpyrrolidinium, N-methyl-N′-propylpyrrolidinium, N,N′-dimethylimidazolium, N-methyl-N′-ethylimidazolium or N-methyl-N′-propylimidazolium.
Embodiment 13. The electrode active layer of any one of the preceding Embodiments, wherein the sulfonated polymer has an average molecular mass of from about 50,000 g/mol to about 2,000,000 g/mol.
Embodiment 14. The electrode active layer of Embodiment 13, wherein the sulfonated polymer has an average molecular mass of from about 70,000 g/mol to about 1,000,000 g/mol.
Embodiment 15. The electrode active layer of any one of the preceding Embodiments, wherein the binder comprises at least 30% by weight of the salt of the sulfonated polymer.
Embodiment 16. The electrode active layer of Embodiment 15, wherein the binder comprises at least 50% by weight of the salt of the sulfonated polymer.
Embodiment 17. The electrode active layer of Embodiment 15 or 16, wherein the binder comprises at least 90% by weight of the salt of the sulfonated polymer.
Embodiment 18. The electrode active layer of any one of the preceding Embodiments, wherein the sulfonate polymer is a copolymer comprising two or more different sulfonated monomers.
Embodiment 19. The electrode active layer of any one of the preceding Embodiments, wherein the sulfonate polymer is a copolymer comprising one or more sulfonated monomers and at least one other monomer, wherein the sulfonated monomers comprise one sulfonate group per monomer, and wherein the at least one other monomer is devoid of sulfonate groups.
Embodiment 20. The electrode active layer of Embodiment 19, wherein the sulfonated monomers comprise one benzenesulfonate group per monomer.
Embodiment 21. The electrode active layer of Embodiment 19 or 20, wherein the at least one other monomer is selected from one or more of 1,2-difluoroethylene, tetrafluoroethylene, styrene, butadiene, maleic anhydride, maleic acid or a salt thereof, acrylic acid or a salt thereof, methacrylic acid or a salt thereof, or butylacrylic acid or a salt thereof.
Embodiment 22. The electrode active layer of any one of the preceding Embodiments, wherein the sulfonated polymer is a sulfonated non-perfluorinated polymer.
Embodiment 23. The electrode active layer of any one of the preceding Embodiments, wherein the sulfonated polymer is a sulfonated non-fluorinated polymer.
Embodiment 24. The electrode active layer of any one of the preceding Embodiments, wherein the sulfonated polymer is not chemically cross-linked.
Embodiment 25. The electrode active layer of any one of the preceding Embodiments, wherein the binder comprises a mixture of two or more different salts of sulfonated polymers, or a mixture of a salt of a sulfonated polymer and at least one other polymer.
Embodiment 26. The electrode active layer of Embodiment 25, wherein the other polymer is selected from PVDF, PTFE, SBR or an acrylic-based polymer.
Embodiment 27. The electrode active layer of any one of the preceding Embodiments, wherein the active material is an amorphous carbon.
Embodiment 28. The electrode active layer of Embodiment 27, wherein the active material is an activated carbon.
Embodiment 29. The electrode active layer of any one of the preceding Embodiments, further comprising a conductive material.
Embodiment 30. The electrode active layer of Embodiment 29, wherein the conductive material is a conductive carbon.
Embodiment 31. The electrode active layer of any one of the preceding Embodiments, having a thickness of from 1 μm to 20 μm.
Embodiment 32. The electrode active layer of any one of the preceding Embodiments, wherein the binder is present in an amount of from 1 to 30 wt % of the electrode active layer.
Embodiment 33. The electrode active layer of Embodiment 32, wherein the binder is present in an amount of from 2 to 20 wt % of the electrode active layer.
Embodiment 34. A composite electrode, comprising:
   the electrode active layer of any one of Embodiments 1 to 33 on a conductive surface.
Embodiment 35. An energy storage device comprising a composite electrode according to Embodiment 34.
Embodiment 36. The energy storage device of Embodiment 34 which is a supercapacitor.
Embodiment 37. The energy storage device of Embodiment 34 which is a battery.
Embodiment 38. The energy storage device of any one of Embodiments 35 to 37, comprising two composite electrodes, wherein each composite electrode comprises a different binder.
Embodiment 39. The energy storage device of Embodiment 38, wherein the different binders comprise different sulfonated polymers.
Embodiment 40. Use of a salt of a sulfonated polymer as a binder in an electrode active layer of a composite electrode.
Embodiment 41. An electrode slurry for producing an electrode active layer, the electrode slurry comprising:
   an active material;
   a binder comprising a salt of a sulfonated polymer; and solvent.
Embodiment 42. The electrode slurry of Embodiment 41, comprising from 50 to 95 wt % solvent.
Embodiment 43. The electrode slurry of Embodiment 41 or Embodiment 42, wherein the solvent is water.
Embodiment 44. The electrode slurry of any one of Embodiments 41 to 43, comprising from 1 to 30 wt % of binder on a solids basis.
Embodiment 45. The electrode slurry of Embodiment 41, comprising from 2 to 20 wt % of binder on a solids basis.
Embodiment 46. The electrode slurry of any one of Embodiments 41 to 45, wherein the active material is an amorphous carbon.
Embodiment 47. The electrode slurry of Embodiment 46, wherein the active material is an activated carbon.
Embodiment 48. The electrode slurry of any one of Embodiments 41 to 47, comprising from 50 to 99 wt % of active material on a solids basis.
Embodiment 49. The electrode slurry of any one of Embodiments 41 to 47, wherein the slurry is a substantially homogenous dispersion of the active material.
Embodiment 50. The electrode slurry of any one of Embodiments 41 to 49, further comprising a conductive material.
Embodiment 51. The electrode slurry of Embodiment 50, wherein the conductive material is a conductive carbon.
Embodiment 52. The electrode slurry of Embodiment 50 or 51, comprising from 5 to 25 wt % of conductive material on a solids basis.
Embodiment 53. The electrode slurry of any one of Embodiments 41 to 52, wherein the sulfonated polymer is according to any one of Embodiments 2 to 8, 13 to 14 or 18 to 24.
Embodiment 54. The electrode slurry of any one of Embodiments 41 to 53, wherein the salt of the sulfonated polymer is according to any one of Embodiments 9 to 12.
Embodiment 55. A method of making an electrode active layer, comprising:
   applying an electrode slurry according to any one of Embodiments 41 to 54 to a current collector; and
   drying the electrode slurry to remove the solvent.

### EXAMPLES

The present invention will now be described with reference to the following examples which should be considered in all respects as illustrative and non-restrictive.

Effective capacitance is calculated using Equation 1:

$$Effective Capcacitance ( F / {cm}^{2} ) = \frac{Capacitance of device ( F )}{Volume of one active layer ( {cm}^{3} )} \qquad Equation 1$$

Effective ESR is calculated using Equation 2:

$$Effective ESR ( m Ω \cdot {cm}^{2} ) = ESR of device ( m Ω ) \times Area of one active electrode ( {cm}^{2} ) \qquad Equation 2$$

### Example 1

### Polystyrene Sulfonate Binder Mixture (NaPSS-100)

Water (3270 g), sodium polystyrene sulfonate (PSS; 46 g, MW=1,000,000 g/mol, Sigma Aldrich), carbon black (366 g), and activated carbon (1338 g) were mixed and suspended prior to physical coating on aluminium foil using a K-bar, doctor blade, or slot die. The typical coating thickness as applied was of the order of 1 μm-100 μm depending on the device specifications.

### Test Results and Discussion

The coating produced from the above binder mixture was applied to a thickness of 50 μm, at 130C under a vacuum of less than 30 mbar and the coated electrode formed into a supercapacitor in a laminate package. The sample was tested in a test cell arrangement at 70° C. at 2.5 V.

A comparable coating prepared using CMC was also prepared in an otherwise identical supercapacitor. The initial effective ESR and capacitance for the PSS sample showed a significant reduction in effective ESR compared to the CMC sample as per Table 1 below:

TABLE 1
Initial capacitance and ESR data for Example 1 (Na-PSS-100)

| | | | Dry | | Capacitive | Effective |
|---|---|---|---|---|---|---|
| | ESR | C | Thickness | Area | density | ESR |
| | (mΩ) | (F) | (μm) | (cm²) | (F/cm³) | (mΩ/cm²) |
| PSS | 19.1 | 4.4 | 52.4 | 28.9 | 29.1 | 551 |
| (Example 1) | | | | | | |
| CMC | 25 | 5.5 | 58 | 28.9 | 32.8 | 722 |
| (Comparative | | | | | | |
| Example) | | | | | | |

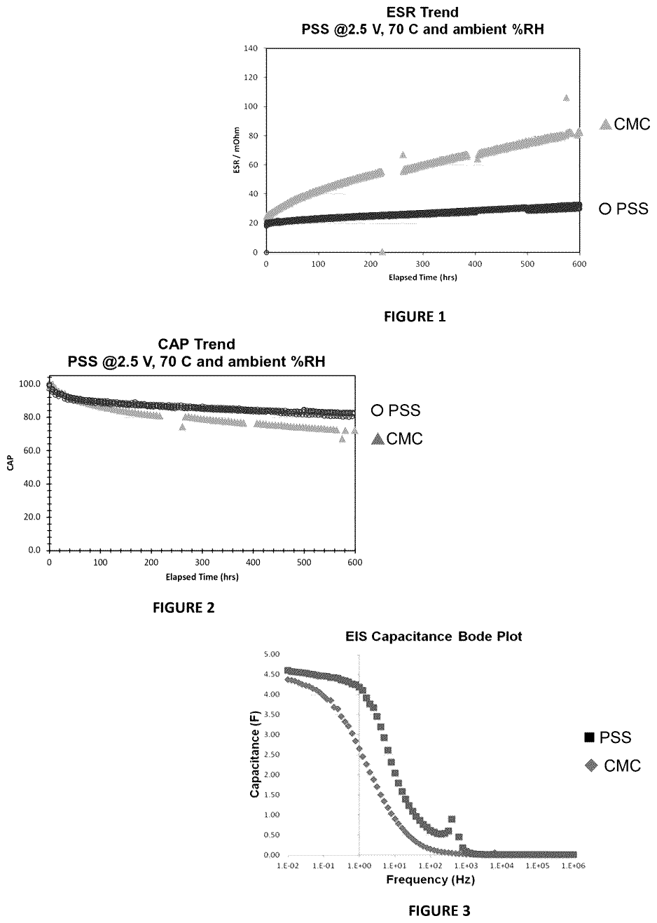

The ESR and capacitance of the supercapacitor was tested by regular discharge measurements (see FIGS. 1 and 2). As evidenced by these data, the ESR rise is much slower using PSS as a binder compared to using CMC, and the capacitance is lost more slowly. The PSS capacitors performed better after 600 hours than the CMC capacitors performed at 50 hours.

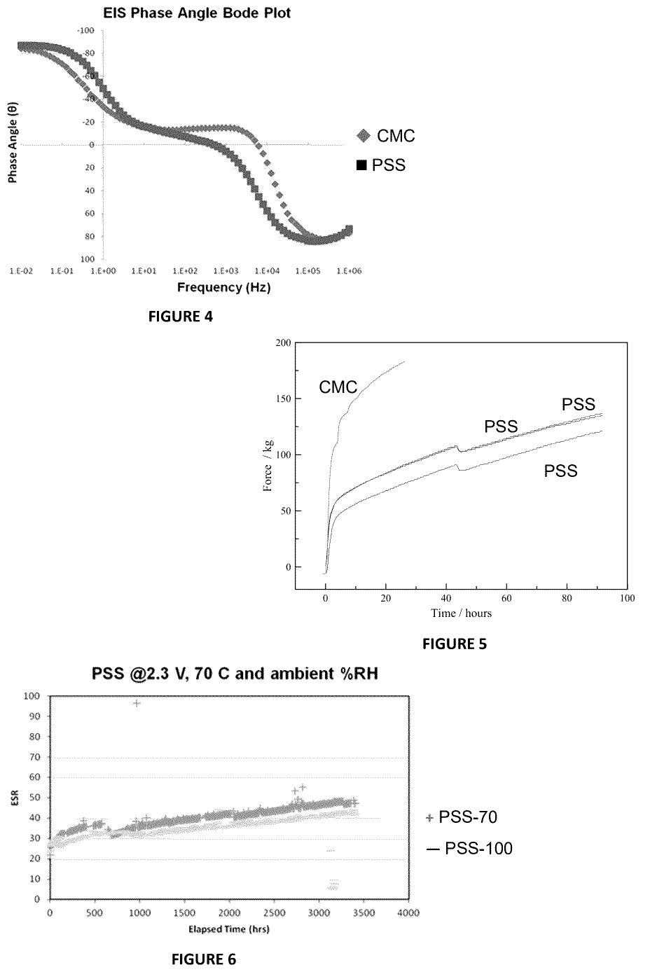

The PSS supercapacitor also show an improved frequency response for capacitance relative to the otherwise identical CMC supercapacitor (see FIG. 3). The PSS supercapacitor −45° phase transition occurred at around 1.1 Hz, compared to the comparable CMC transition at 0.5 Hz (see FIG. 4).

The PSS coated supercapacitor also demonstrated improved outgassing properties relative to an otherwise identical CMC supercapacitor. Electrodes made with either PSS or CMC as a binder were assemble in a two-electrode configuration and charged to 2.5 V in a sealed laminate package at 65° C. The laminate cell was placed between two flat plates with one plate fixed and the other plate able to slide on bearings. A load cell was placed on the freely moving flat plate. The outgassing in the laminate cell was monitored as the force applied to the load cells as gas was generated in the laminate package and the results shown in FIG. 5. There was less gas generated in the cells for the supercapacitors that used PSS binders as judged by the lower force exerted on the load cell at 100 hours than the equivalent CMC capacitor at 10 hours.

The NaPSS binder was most effective at a pH close to 7.

### Example 2

### Polystyrene Sulfonate Binder Mixture (NaPSS-70)

Water (2250 g), sodium polystyrene sulfonate (PSS; 74.1 g, MW=70,000 g/mol), carbon black (147 g), and activated carbon (526 g) were mixed and suspended prior to physical coating on aluminium foil using a slot die. The typical coating thickness as applied was of the order of 1 μm-100 μm depending on the device specifications.

### Test Results and Discussion

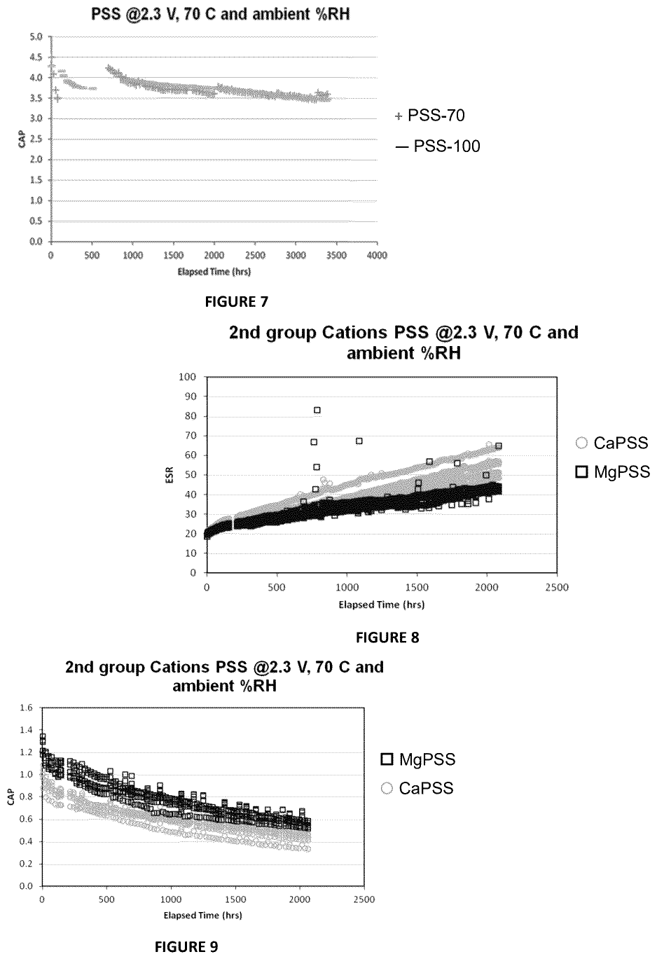

Life testing for the supercapacitors containing 70,000 g/mol PSS binder and 1,000,000 g/mol PSS binder were very similar and both exhibited substantial benefits over the CMC supercapacitor in terms of the ESR rise rate and C-Loss rates (see FIGS. 6 and 7). Consistency in data across the different molecular weights of PSS show that the benefits of PSS are independent of polymer molecular weight in this range.

### Example 3

### Polystyrene Sulfonate Binder Mixture (X-PSS-75)

Electrode active layers were made using different PSS salt binders as described below: Ca-PSS-75, Mg-PSS-75, Li-PSS-75, K-PSS-75, and Cs-PSS-75.

PSS (acid, 75,000 MW, 18% in H₂O) (7.52 g) was dissolved in deionised water (29.7 g) with magnetic stirring. The mixture was adjusted to pH 7 using Ca(OH)₂ (saturated solution) and tetrafluoroboric acid. Methanol (0.83 g) was added and stirred for 10 mins. Carbon black (2.72 g) was added and the mixture was stirred for 2 hours. Activated carbon (9.45 g) was added and stirred overnight and finally the mixture was dispersed for 1 minute.

PSS (acid, 75,000 MW, 18% in H₂O) (3.82 g) was dissolved in deionised water (14.8 g) with magnetic stirring. The mixture was pH adjusted to 7 by addition of Mg(OH)₂ (~0.14 g suspended in a minimal amount of water). Methanol (0.44 g) was added and stirred for 10 mins. Carbon black (1.30 g) was added and the mixture was stirred for 2 hours. Activated carbon (4.72 g) was added and stirred overnight and finally the mixture was dispersed for 1 minute.

PSS (acid, 75,000 MW, 18% in H₂O) (3.74 g) was diluted in deionised water (16.32 g) with magnetic stirring. The mixture was pH adjusted to 8 using LiGH (~0.088 g dissolved in a minimal amount of water). Tetrafluoroboric acid (48% in water) was added dropwise to adjust the pH to 8. Methanol (0.41 g) was added and stirred for 10 mins. Carbon Black (1.29 g) was added and the mixture was stirred for 2 hours. Activated carbon (4.65 g) was added and stirred overnight and finally the mixture was dispersed for 1 minute.

PSS (acid, 75,000 MW, 18% in H₂O) (3.76 g) was dissolved in deionised water (16.31 g) with magnetic stirring. The mixture was pH adjusted to 7-8 using KOH (~0.21 g dissolved in a minimal amount of water) and tetrafluoroboric acid. Methanol (0.41 g) was added and stirred for 10 mins. Carbon black (1.28 g) was added and the mixture was stirred for 2 hours. Activated carbon (4.61 g) was added and stirred overnight and finally the mixture was dispersed for 1 minute.

PSS (acid, 75,000 MW, 18% in H₂O) (3.75 g) was dissolved in deionised water (16.59 g) with a magnetic stirrer bar. The mixture was pH adjusted to 7 using CsOH (added portion-wise as a solid) and tetrafluoroboric acid. Methanol (0.42 g) was added and stirred for 10 mins. Carbon black (1.32 g) was added and the mixture was stirred for 2 hours. Activated carbon (4.73 g) was added and stirred overnight and finally the mixture was dispersed for 1 minute.

Each of the above mixtures were then physically coated on aluminium foil using a K-bar. The typical coating thickness as applied was of the order of 1 μm-100 μm depending on the device specifications.

### Test Results and Discussion

The initial effective capacitance and ESR results for a range of metal cations including sodium, calcium, magnesium, potassium, caesium, and lithium are shown in Table 2 below:

TABLE 2
Initial capacitance and ESR data for Example
3 (X-PSS-75; X = K, Li, Cs, Mg, Ca)

| | | | | Capacitive | |
|---|---|---|---|---|---|
| PSS | ESR | | Thickness | density | Effective ESR |
| cation | (mΩ) | C (F) | (μm) | (F/cm³) | (mΩ/cm²) |
| K | 50.7 | 1.057 | 10.6 | 34 | 1466 |
| Li | 20.6 | 1.112 | 10.0 | 38 | 594 |
| Cs | 36.7 | 1.214 | 12.1 | 35 | 1062 |
| Mg | 22.0 | 1.266 | 15.8 | 28 | 635 |
| Ca | 24.3 | 0.999 | 12.0 | 29 | 702 |

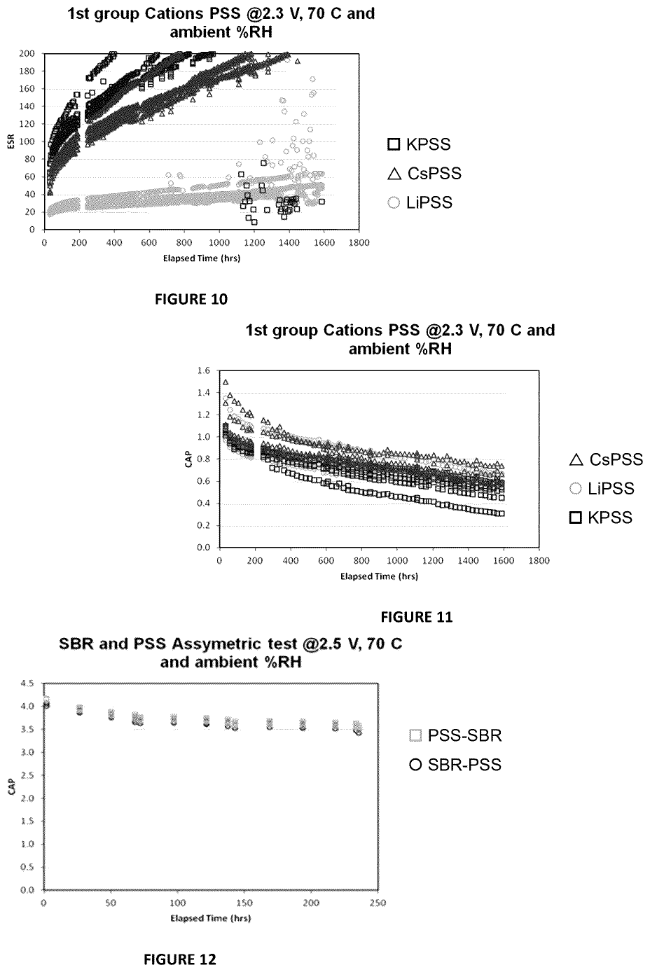

Life testing for the supercapacitors containing X-PSS-75 binders (X=K, Li, Cs, Mg, Ca) have ESR rise rates and C-Loss rates as shown in FIGS. 8-9 (Ca, Mg) and FIGS. 10-11 (Li, K, Cs).

Data in Table 2 and Table 1 and FIGS. 1-11 suggest that Na, Li, Mg and Ca are particularly suitable counterions for PSS binders in supercapacitor devices with activated carbon as the active electrode material.

### Example 3

### Asymmetric/Mixed Binder Devices

A capacitor was constructed with PSS as a binder (NaPSS-70) on the positive electrode and SBR binder on the negative electrode (PSS-SBR) and vice versa (SBR-PSS).

### Test Results and Discussion

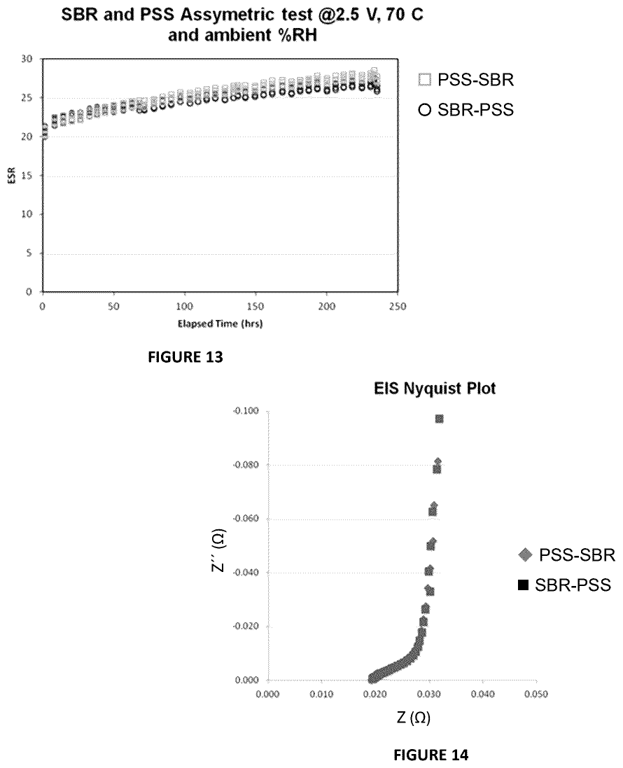

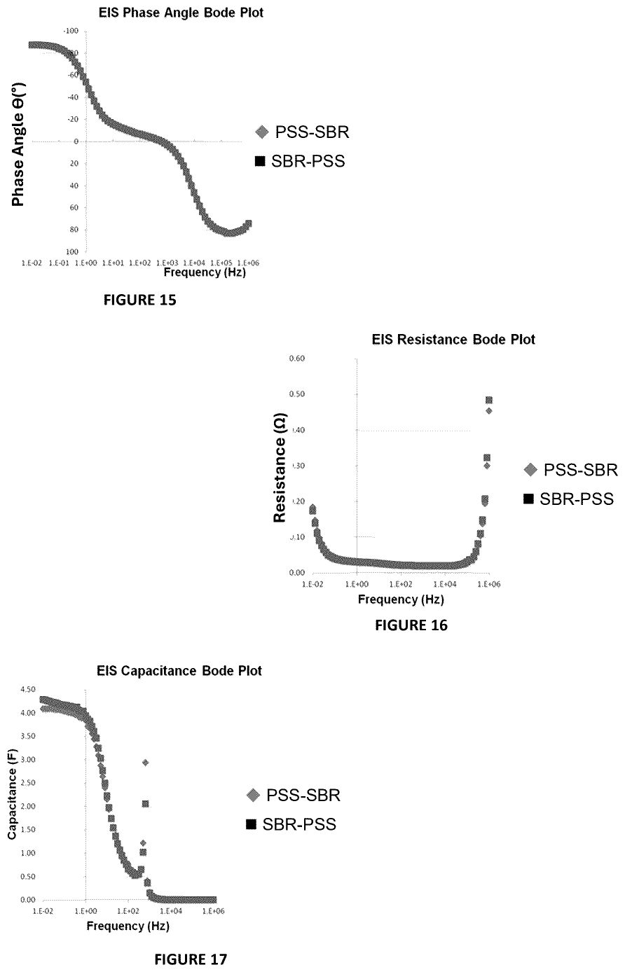

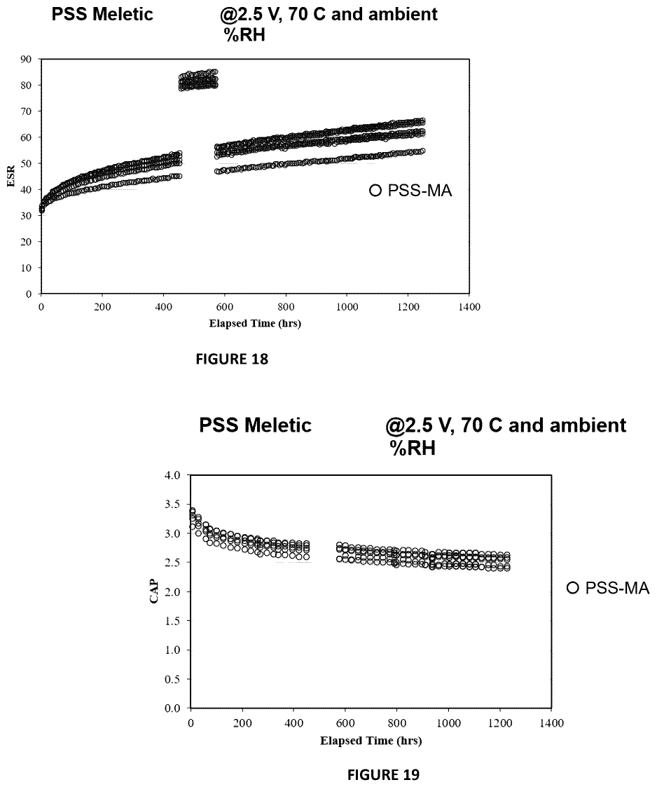

C-Loss rates and ESR rise rates are shown for an asymmetric device in FIGS. 12 and 13, respectively. Other data in FIGS. 14-17 show that PSS can be used on the positive or negative side either in isolation or in combination with existing binders with little detrimental effect on lifetime or performance of the device.

### Example 4

### Polystyrene Sulfonate Maleic Anhydride Copolymer Binder Mixture (NaPSS-coMA-20)

Poly(4-styrenesulfonic acid-co-maleic acid) sodium salt (20,000 MW, Sigma Aldrich) (2.31 g) was dissolved in deionised water (50.12 g) with magnetic stirring. The mixture was stirred for 1 h. Carbon black (9.74 g) was added and the mixture was mixed for 1 h, then dispersed in a high-shear mixer for 1 min. Activated carbon (20.24 g) was mixed and dispersed with addition of water (12.58 g). The coatings were then coated with a 20 μm k-bar.

### Test Results and Discussion

Final thicknesses: 33.6±4.9 μm. Resistance: 6.53m). The system passed the 1000 h life test at 2.5 V. The poly(4-styrenesulfonic acid-co-maleic acid) sodium salt is a viable binder, with leakage results in line with existing PSS data.

It will be apparent to the person skilled in the art that while the invention has been described in some detail for the purposes of clarity and understanding, various modifications and alterations to the embodiments and methods described herein may be made without departing from the scope of the inventive concept disclosed in this specification.

1. An electrode active layer for an energy conversion or storage device, comprising:
an active material; and
a binder comprising a salt of a sulfonated polymer.

2. The electrode active layer of claim 1, wherein the sulfonated polymer comprises substituted C₂ to C₆ linear or branched alkene monomers, wherein the substituted C₂ to C₆ linear or branched alkene comprises, as a substituent, one or more of: —R₁SO₃⁻, —R₁ArSO₃⁻, —ArR₁SO₃⁻, —ArSO₃— or —C(═O)NHR₁SO₃⁻, —C(═O)NHR₁ArSO₃⁻, —C(═O)NHArR₁SO₃⁻;
wherein R₁═C₁ to C₆ linear or branched alkyl group or a bond; and
Ar=aryl group, optionally a phenyl group.

3. The electrode active layer of claim 1, wherein the sulfonated polymer comprises benzenesulfonate groups.

4. (canceled)

5. The electrode active layer of claim 1, wherein the sulfonated polymer comprises one or more monomers selected from: styrene sulfonate, vinyl sulfonate, 2-acrylamido-2-methyl-1-propanesulfonate, 2-propene-1-sulfonate, or 2-methyl-2-propene-1-sulfonate.

6. The electrode active layer of claim 1, wherein the salt of the sulfonated polymer comprises one or more counterions selected from: a Group I metal cation, a Group II metal cation, a transition metal cation, a quaternary ammonium cation, or a nitrogen-containing heterocyclic cation.

7. The electrode active layer of claim 1, wherein the salt of the sulfonated polymer comprises one or more counterions selected from the group consisting of: a lithium cation, a potassium cation, a sodium cation, a caesium cation, a magnesium cation, a calcium, an optionally substituted alkylammonium cation, a 2-(methylthio)ethylammonium cation, and a nitrogen-containing heterocyclic cation.

8. (canceled)

9. The electrode active layer of claim 1, wherein the sulfonated polymer has an average molecular mass of from about 20,000 g/mol to about 2,000,000 g/mol.

10. The electrode active layer of claim 1, wherein the binder comprises at least 30% by weight of the salt of the sulfonated polymer.

11. The electrode active layer of claim 1, wherein the sulfonate polymer is a copolymer comprising two or more different sulfonated monomers.

12. The electrode active layer of claim 1,
wherein the sulfonate polymer is a copolymer comprising one or more sulfonated monomers and at least one other monomer,
wherein the sulfonated monomers comprise one sulfonate group per monomer, and
wherein the at least one other monomer is devoid of sulfonate groups, and wherein the at least one other monomer is selected from one or more of 1,2-difluoroethylene, tetrafluoroethylene, styrene, butadiene, maleic anhydride, maleic acid or a salt thereof, acrylic acid or a salt thereof, methacrylic acid or a salt thereof, or butylacrylic acid or a salt thereof.

13. The electrode active layer of claim 1, wherein the binder comprises a mixture of two or more different salts of sulfonated polymers, or a mixture of a salt of a sulfonated polymer and at least one other polymer.

14. The electrode active layer of claim 1, wherein the active material is an amorphous carbon.

15. The electrode active layer of claim 1, further comprising a conductive material.

16. A composite electrode for a supercapacitor, comprising: the electrode active layer of claim 1 on a conductive surface.

17-19. (canceled)

20. An electrode slurry for producing an electrode active layer, the electrode slurry comprising:
an active material;
a binder comprising a salt of a sulfonated polymer; and
solvent.

21. The electrode slurry of claim 20, comprising from 50 to 95 wt % solvent and/or from 1 to 30 wt % of binder on a solids basis.

22. (canceled)

23. The electrode slurry of claim 20, wherein the slurry is a substantially homogenous dispersion of the active material.

24. (canceled)

25. The composite electrode of claim 16, wherein in the electrode active layer,
the binder comprises a salt of a sulfonated polymer that comprises one or more monomers selected from: styrene sulfonate, vinyl sulfonate, 2-acrylamido-2-methyl-1-propanesulfonate, 2-propene-1-sulfonate, or 2-methyl-2-propene-1-sulfonate; and
the active layer comprises amorphous carbon and a conductive material.

26. The electrode slurry of claim 23, wherein the active material comprises an amorphous carbon and a conductive material.

27. The electrode slurry of claim 20, wherein the solvent is water.
